(19) United States
(12) Patent Application Publication
(10) Pub. No.: US 2026/0370190 A1
(43) Pub. Date: Nov. 19, 2026

(54) TRANSMISSION CIRCUIT AND COMMUNICATION DEVICE INCLUDING SAME

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(21) Appl. No.: 19/731,348

(22) Filed: Jul. 6, 2026

Related U.S. Application Data
(63) Continuation of application No. PCT/JP2025/002808, filed on Jan. 29, 2025.

(30) Foreign Application Priority Data
Feb. 9, 2024 (JP) 2024-018320

(51) Int. Cl. H03F 1/02; H03F 3/24; H03H 11/16; H04B 1/04

(52) U.S. Cl. CPC H03F 1/0288; H03F 3/245; H03H 11/16; H04B 1/0458; H04B 1/0483; H03F 2200/451; H04B 2001/045

(57) ABSTRACT

A transmission circuit includes an input terminal that receives a radio frequency signal, output terminals, amplification circuits, a connection line, output circuits, and switches. Each amplification circuit amplifies the radio frequency signal received by the input terminal. The output circuit transfers the signal amplified by the amplification circuit to the output terminal. The output circuit transfers the signal amplified by the amplification circuit to the output terminal. Each amplification circuit includes a carrier amplifier, a peak amplifier, and a hybrid coupler. In each amplifier, the carrier amplifier and the peak amplifier are connected to two input terminals of the hybrid coupler, respectively. The corresponding output circuit is connected to one output terminal of the hybrid coupler. The switch is connected to the other output terminal of the hybrid coupler. The one output terminals of the hybrid couplers are connected to each other through a connection line.

### CROSS REFERENCE TO RELATED APPLICATION

This is a continuation of International Application No. PCT/JP2025/002808 filed on Jan. 29, 2025 which claims priority from Japanese Patent Application No. 2024-018320 filed on Feb. 9, 2024. The contents of these applications are incorporated herein by reference in their entireties.

### BACKGROUND OF THE DISCLOSURE

### Field of the Disclosure

The present disclosure relates to a transmission circuit and a communication device including the same, or more specifically, to a technique for enhancing robustness against a load variation in a transmission circuit provided with amplifiers.

### Description of the Related Art

Japanese Unexamined Patent Application Publication No. 2013-85179 discloses a power amplification circuit that includes an amplifier output phase shifter connected between an output terminal of a carrier amplifier (a first amplifier) and an output terminal of a peak amplifier (a second amplifier), and a transformer connected between the amplifier output phase shifter and the output terminal of the peak amplifier.

### BRIEF SUMMARY OF THE DISCLOSURE

The power amplification circuit disclosed in Japanese Unexamined Patent Application Publication No. 2013-85179 is a so-called Doherty amplification circuit. In the power amplification circuit of Japanese Unexamined Patent Application Publication No. 2013-85179, impedances at the two amplifiers vary in a case of variations in load impedance to be connected to the output terminals of the power amplification circuit. Accordingly, there is a case where the output power from each amplifier varies and becomes unstable.

The present disclosure has been made to solve the above-mentioned problem, and a possible benefit thereof is to enhance robustness against a load variation in a transmission circuit provided with amplifiers.

A transmission circuit according to the present disclosure amplifies a radio frequency signal and transmits the amplified signal to a radiating element. The transmission circuit includes an input terminal that receives the radio frequency signal, a first output terminal and a second output terminal for connection to the radiating element, a first amplification circuit and a second amplification circuit, a connection line, a first output circuit and a second output circuit, and a first switch and a second switch. The first amplification circuit and the second amplification circuit amplify the radio frequency signal received by the input terminal. The connection line connects the first amplification circuit to the second amplification circuit. The first output circuit is connected to the first amplification circuit and configured to transfer the amplified signal to the first output terminal. The second output circuit is connected to the second amplification circuit and configured to transfer the amplified signal to the second output terminal. The first amplification circuit includes a first carrier amplifier, a first peak amplifier, and a first hybrid coupler. The second amplification circuit includes a second carrier amplifier, a second peak amplifier, and a second hybrid coupler. Each of the first hybrid coupler and the second hybrid coupler includes a first phase shifting line, a second phase shifting line, a third phase shifting line, and a fourth phase shifting line which are annularly connected. A first connection node between the first phase shifting line and the second phase shifting line of the first hybrid coupler is connected to an output end of the first carrier amplifier. A second connection node between the first phase shifting line and the third phase shifting line of the first hybrid coupler is connected to an output end of the first peak amplifier. A third connection node between the second phase shifting line and the fourth phase shifting line of the first hybrid coupler is connected to a ground potential through the first switch. A fourth connection node between the third phase shifting line and the fourth phase shifting line of the first hybrid coupler is connected to the first output terminal through the first output circuit. A fifth connection node between the first phase shifting line and the second phase shifting line of the second hybrid coupler is connected to an output end of the second carrier amplifier. A sixth connection node between the first phase shifting line and the third phase shifting line of the second hybrid coupler is connected to an output end of the second peak amplifier. A seventh connection node between the second phase shifting line and the fourth phase shifting line of the second hybrid coupler is connected to the ground potential through the second switch. An eighth connection node between the third phase shifting line and the fourth phase shifting line of the second hybrid coupler is connected to the second output terminal through the second output circuit. The connection line is connected between the fourth connection node and the eighth connection node. Radio frequency signals having different phases from each other are supplied to the first amplification circuit and the second amplification circuit. The connection line has an electrical length equal to at least one of the phase shifting lines in the first hybrid coupler and the second hybrid coupler.

In the transmission circuit according to the present disclosure, the radio frequency signals provided with the phase difference are supplied to the two amplification circuits, and output ends of the two amplification circuits are configured to be connected to each other with a connection line. Moreover, the connection line has the electrical length equal to each phase shifting line of the hybrid couplers. According to the above-described configuration, variations in load impedance in the respective amplification circuits, that is to say, variations in output power therefrom are set to opposite directions from each other in a case of the occurrence of a load variation. Accordingly, the variations in output power associated with the variations in load impedance at the respective amplifiers are offset at the output terminals, so that a variation in output power from the transmission circuit as a whole can also be suppressed in the case of the occurrence of a load variation. Therefore, it is possible to enhance robustness against the load variation in the transmission circuit.

### BRIEF DESCRIPTION OF THE SEVERAL VIEWS OF THE DRAWINGS

FIG. 1 is a schematic configuration diagram of a communication device to which a transmission circuit according to an embodiment is applied.

FIG. 2 is a diagram showing a detailed configuration of a power amplification circuit in FIG. 1.

FIG. 3 is a diagram for explaining a circuit configuration in a case of transmission from an output terminal T1.

FIG. 4 is a diagram for explaining a circuit configuration in a case of transmission from an output terminal T2.

FIG. 5 is a diagram for explaining output states of respective amplifiers at the time of high output in Example 1.

FIG. 6 is a diagram for explaining the output states of the respective amplifiers in back-off at the time of high output.

FIG. 7 is a diagram for explaining output states of the respective amplifiers at the time of low output in Example 1.

FIG. 8 is a diagram for explaining the output states of the respective amplifiers in the back-off at the time of low output.

FIG. 9 is a diagram for explaining output states of the respective amplifiers at the time of high output in Example 2.

FIG. 10 is a diagram for explaining the output states of the respective amplifiers in the back-off at the time of high output.

FIG. 11 is a diagram for explaining output states of the respective amplifiers at the time of low output in Example 2.

FIG. 12 is a diagram for explaining the output states of the respective amplifiers in the back-off at the time of low output.

FIG. 13 is a diagram for explaining output states of the respective amplifiers at the time of high output in Example 3.

FIG. 14 is a diagram for explaining the output states of the respective amplifiers in the back-off at the time of high output.

FIG. 15 is a diagram for explaining output states of the respective amplifiers at the time of low output in Example 3.

FIG. 16 is a diagram for explaining the output states of the respective amplifiers in the back-off at the time of low output.

FIG. 17 is a diagram for explaining output states of the respective amplifiers at the time of high output in Example 4.

FIG. 18 is a diagram for explaining the output states of the respective amplifiers in the back-off at the time of high output.

FIG. 19 is a diagram for explaining output states of the respective amplifiers at the time of low output in Example 4.

FIG. 20 is a diagram for explaining the output states of the respective amplifiers in the back-off at the time of low output.

### DETAILED DESCRIPTION OF THE DISCLOSURE

An embodiment of the present disclosure will be described below in detail with reference to the drawings. Note that identical or equivalent portions in the drawings will be denoted by the same reference signs and explanations thereof will not be repeated.

### Embodiment

### (Overall Configuration of Communication Device)

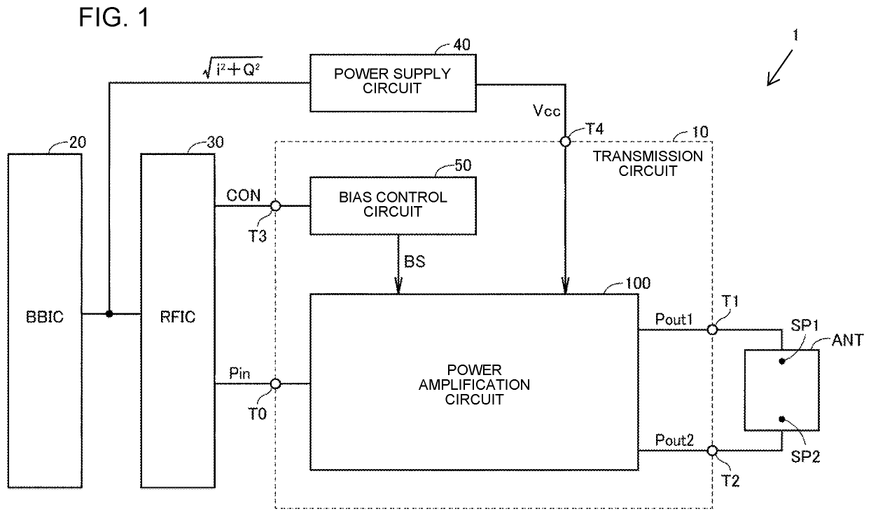

FIG. 1 is a schematic configuration diagram of a communication device 1 to which a transmission circuit 10 according to an embodiment is applied. Examples of the communication device 1 include a portable terminal such as a mobile phone, a smartphone, or a tablet, a personal computer equipped with a communication function, or the like.

With reference to FIG. 1, the communication device 1 includes an antenna ANT, the transmission circuit 10, a BBIC (baseband integrated circuit) 20 that constitutes a baseband signal processing circuit, an RFIC (radio frequency integrated circuit) 30, and a power supply circuit 40. The transmission circuit 10 includes input terminals T0, T3, and T4, output terminals T1 and T2, a bias control circuit 50, and a power amplification circuit 100. In general, the communication device 1 up-converts an intermediate frequency (IF) signal transferred from the BBIC 20 into a radio frequency (RF) signal at the RFIC 30, amplifies the radio frequency signal at the power amplification circuit 100, and radiates the amplified signal from the antenna ANT.

The RFIC 30 represents an example of a signal processing circuit that processes radio frequency signals. The RFIC 30 up-converts the intermediate frequency signal transferred from the BBIC 20 into the radio frequency signal, and outputs the generated radio frequency signal to the transmission circuit 10 through the input terminal T0.

The bias control circuit 50 accepts a control signal CON which is received from the RFIC 30 through the input terminal T3. Based on the control signal CON, the bias control circuit 50 generates bias signals BS for controlling magnitudes and supply timing of bias currents of amplifiers included in the power amplification circuit 100, and outputs the bias signals BS to the power amplification circuit 100.

The power amplification circuit 100 generates output signals Pout1 and Pout2 by amplifying an input signal Pin which is received from the RFIC 30 through the input terminal T0.

The antenna ANT is, for example, a patch antenna in the form of a flat plate. The output terminal T1 of the transmission circuit 10 is connected to a power feeding point SP1 of the antenna ANT. The output terminal T2 of the transmission circuit 10 is connected to a power feeding point SP2 of the antenna ANT. The antenna ANT radiates, as radio waves, the output signals Pout1 and Pout2 being the radio frequency signals outputted from the transmission circuit 10.

### (Detailed Configurations of the Transmission Circuit)

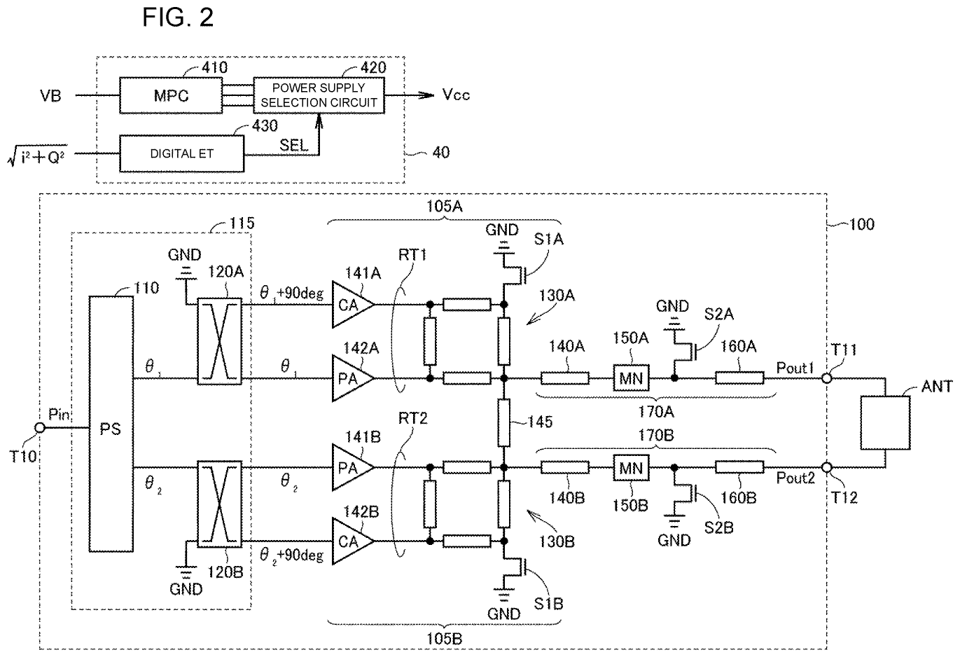

Next, detailed configurations of the power amplification circuit 100 in the transmission circuit 10 and of the power supply circuit 40 will be described by using FIG. 2.

The power supply circuit 40 represents an example of a so-called digital tracker, which is capable of supplying multiple power supply voltages Vcc at different voltage levels to the power amplification circuit 100. The power supply circuit 40 includes a multilevel power converter (MPC) 410, a power supply selection circuit 420, and a digital envelope tracker (digital ET) 430.

Although not shown in FIG. 2, the MPC 410 includes multiple DC/DC converters. The MPC 410 converts a battery voltage VB supplied from an external battery into different voltage levels, and supplies the voltage levels to the power supply selection circuit 420.

The digital ET 430 receives an I/Q waveform signal of a transmission signal from the BBIC 20, and tracks an envelope of the transmission signal in accordance with a digital ET mode. The digital ET 430 generates a selection signal SEL corresponding to a voltage level of the envelope of the transmission signal, and outputs the selection signal SEL to the power supply selection circuit 420.

The power supply selection circuit 420 selects a voltage corresponding to the selection signal SEL out of the multiple voltage levels supplied from the MPC 410, and supplies the voltage as the power supply voltage Vcc to the power amplification circuit 100 through the input terminal T4.

The power amplification circuit 100 includes an input terminal T10, output terminals T11 and T12, a branch circuit 115, amplification circuits 105A and 105B, output circuits 170A and 170B, and a connection line 145. The input terminal T10 is connected to the input terminal T0 of the power amplification circuit 100. The output terminals T11 and T12 are connected to the output terminals T1 and T2 of the power amplification circuit 100, respectively.

The branch circuit 115 includes a phase shifting (PS) circuit 110, and hybrid couplers 120A and 120B. The phase shifting circuit 110 divides the input signal Pin from the RFIC 30 received at the input terminal T10 into signals for two routes, and provides the two divided signals θ₁ and θ₂ with a phase difference equal to 90°. The hybrid coupler 120A is connected to one of the divided routes (a first route) while the hybrid coupler 120B is connected to the other of the divided routes (a second route). As will be described later, in a case of outputting the radio frequency signal from the output terminal T1, a signal to be outputted to the second route has a phase that is advanced by 90° relative to the signal to be outputted to the first route (θ₂=θ₁+90°). Meanwhile, in a case of outputting the radio frequency signal from the output terminal T2, the signal to be outputted to the second route has a phase that is delayed by 90° relative to the signal to be outputted to the first route (θ₂=θ₁−90°).

The first route divided by the phase shifting circuit 110 is connected to one input terminal of the hybrid coupler 120A. The other input terminal of the hybrid coupler 120A is connected to a ground potential GND. The hybrid coupler 120A further divides the signal from the phase shifting circuit 110 into signals for two routes, and provides the two divided signals with a phase difference equal to 90°.

Likewise, the second route divided by the phase shifting circuit 110 is connected to one input terminal of the hybrid coupler 120B. The other input terminal of the hybrid coupler 120B is connected to the ground potential GND. The hybrid coupler 120B further divides the signal from the phase shifting circuit 110 into signals for two routes, and provides the two divided signals with a phase difference equal to 90°.

The amplification circuit 105A includes a carrier amplifier 141A, a peak amplifier 142A, a hybrid coupler 130A, and a switch S1A. In the amplification circuit 105A, an output end of the carrier amplifier 141A is connected to one input terminal of the hybrid coupler 130A, while an output end of the peak amplifier 142A is connected to the other input terminal of the hybrid coupler 130A. A phase of a signal to be inputted to the carrier amplifier 141A is advanced by 90° relative to a phase to be inputted to the peak amplifier 142A.

One output terminal of the hybrid coupler 130A is connected to the ground potential GND through the switch S1A. The other output terminal of the hybrid coupler 130A is connected to the output terminal T11 through the output circuit 170A.

The output circuit 170A includes phase shifting lines 140A and 160A, a matching circuit 150A, and a switch S2A. The phase shifting line 140A, the matching circuit 150A, and the phase shifting line 160A are serially connected in this order between the other output terminal of the hybrid coupler 130A and the output terminal T11. The switch S2A is connected between the ground potential GND and a line that connects the matching circuit 150A to the phase shifting line 160A.

Likewise, the amplification circuit 105B includes a carrier amplifier 141B, a peak amplifier 142B, a hybrid coupler 130B, and a switch S1B. In the amplification circuit 105B, an output end of the carrier amplifier 141B is connected to one input terminal of the hybrid coupler 130B, while an output end of the peak amplifier 142B is connected to the other input terminal of the hybrid coupler 130B. A phase of a signal to be inputted to the carrier amplifier 141B is advanced by 90° relative to a phase to be inputted to the peak amplifier 142B.

One output terminal of the hybrid coupler 130B is connected to the ground potential GND through the switch S1B. The other output terminal of the hybrid coupler 130B is connected to the output terminal T12 through the output circuit 170B.

The output circuit 170B includes phase shifting lines 140B and 160B, a matching circuit 150B, and a switch S2B. The phase shifting line 140B, the matching circuit 150B, and the phase shifting line 160B are serially connected in this order between the other output terminal of the hybrid coupler 130B and the output terminal T12. The switch S2B is connected between the ground potential GND and a line that connects the matching circuit 150B to the phase shifting line 160B.

The connection line 145 is connected between the other output terminal of the hybrid coupler 130A and the other output terminal of the hybrid coupler 130B. The connection line 145 is, for example, a phase shifting line having an electrical length equivalent to a quarter wavelength of a center frequency in a frequency band of a radio frequency signal being a target of transmission. The connection line 145 can invert a phase of an output signal from the amplification circuit 105A and transfer the phase-inverted output signal to an output end of the amplification circuit 105B. Alternatively, the connection line 145 can invert a phase of an output signal from the amplification circuit 105B and transfer the phase-inverted output signal to an output end of the amplification circuit 105A.

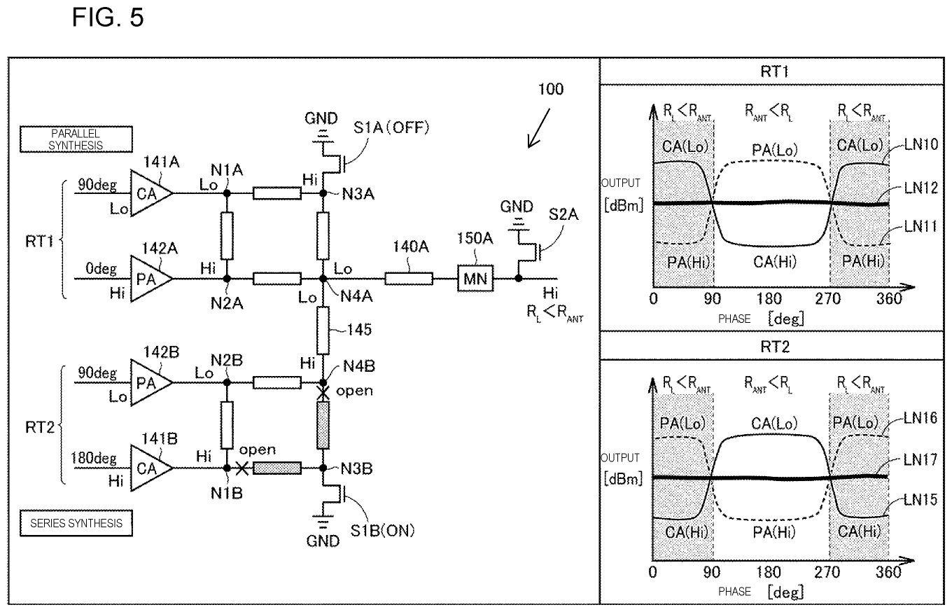

Switching the states of the switches S1A and S1B makes it possible to change a method of synthesizing a signal amplified by the carrier amplifier with a signal amplified by the peak amplifier in each amplification circuit. A specific synthesizing method will be discussed later in detail with reference to FIG. 5 and the like.

The switches S2A and S2B in the output circuits 170A and 170B are switches for selectively switching, between the output terminals T1 and T2 of the power amplification circuit 100, an output port for actually transmitting the radio frequency signal to the antenna ANT. Specifically, the radio frequency signal is transferred from the output terminal T1 to the antenna ANT through the output circuit 170A by making the switch S2A non-conductive while making the switch S2B conductive. On the other hand, the radio frequency signal is transferred from the output terminal T2 to the antenna ANT through the output circuit 170B by making the switch S2B non-conductive while making the switch S2A conductive.

For example, in a case where the antenna ANT is an antenna of a so-called dual-band type configured to output signals in two different frequency bands, the switching of the switches S2A and S2B makes it possible to output the signal in one frequency band (a first frequency band) from the output terminal T1 and to output the signal in the other frequency band (a second frequency band) from the output terminal T2. In this instance, the matching circuit 150A is set in such a way as to match impedances between the power amplification circuit 100 and the antenna ANT in the first frequency band. Meanwhile, the matching circuit 150B is set in such a way as to match impedances between the power amplification circuit 100 and the antenna ANT in the second frequency band.

The phase shifting lines 140A, 140B, 160A, and 160B in the output circuits 170A and 170B are each set to a quarter wavelength of a center frequency in a frequency band of a signal being a target passing through these lines, and configured to invert the phase of the signal passing therethrough. In a case where the switch S2A or S2B is set to the conductive state (that is to say, a short-circuit) by these phase shifting lines, the impedances at the output end of the corresponding amplification circuit and at the output terminal to which the antenna ANT is connected are set to open.

As described above, the output signals from the amplification circuits 105A and 105B can be synthesized at the same phase by inputting the radio frequency signals having the phase difference equivalent to 90° to the two amplification circuits 105A and 105B each including the carrier amplifier, the peak amplifier, and the hybrid coupler, and by connecting the output ends of the amplification circuits 105A and 105B to each other through the connection line 145.

Note that a route on which the signal passes through the amplification circuit 105A will be referred to as a route RT1, and a route on which the signal passes through the amplification circuit 105B will be referred to as a route RT2 in the following description.

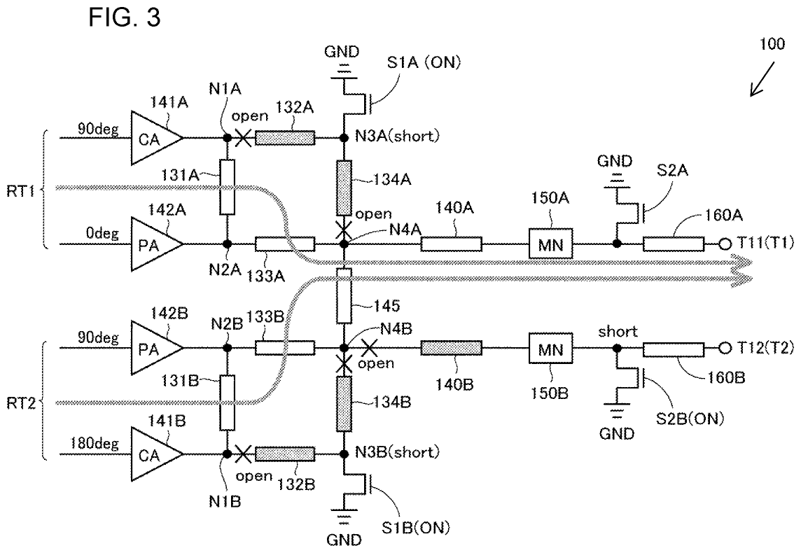

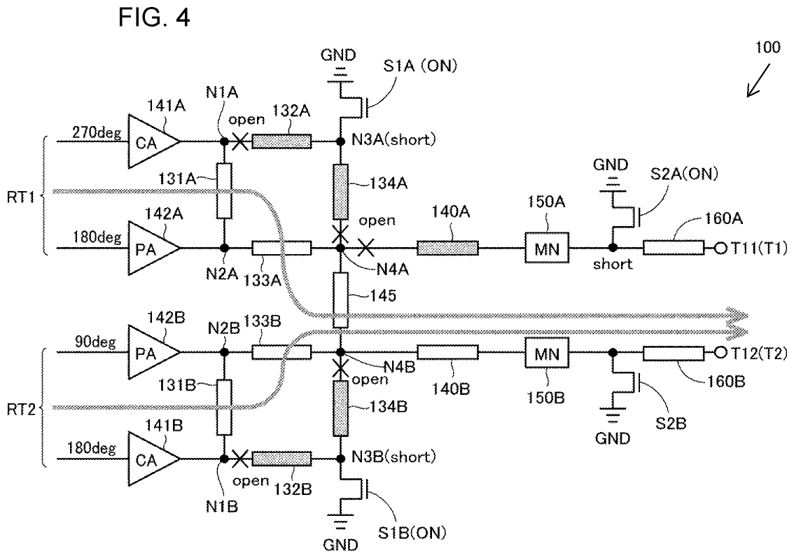

Next, examples of circuit configurations in cases where the radio frequency signal is transmitted from the respective output terminals to the antenna ANT will be described by using FIGS. 3 and 4. Only the configurations downstream of the amplification circuits 105A and 105B in the power amplification circuit 100 are shown in FIGS. 3 and 4. FIG. 3 shows a case where the radio frequency signal is transmitted from the output terminal T1, and FIG. 4 shows a case where the radio frequency signal is transmitted from the output terminal T2.

With reference to FIGS. 3 and 4, each of the hybrid couplers 130A and 130B in the amplification circuits 105A and 105B includes four annularly connected phase shifting lines. The hybrid coupler 130A includes phase shifting lines 131A to 134A, and the hybrid coupler 130B includes phase shifting lines 131B to 134B. Each phase shifting line in each hybrid coupler has an electrical length equivalent to the quarter wavelength of the center frequency in the frequency band of the target of transmission. That is to say, the electrical length of each phase shifting line in each hybrid coupler is equal to the electrical length of the connection line 145. Here, actual electrical lengths of the respective phase shifting lines in the hybrid couplers do not always coincide perfectly with one another. As such, the electrical length of the connection line 145 only needs to coincide with the electrical length of at least one of the phase shifting lines of the hybrid couplers.

A connection node N1A between the phase shifting line 131A and the phase shifting line 132A corresponds to one input terminal of the hybrid coupler 130A, and the output end of the carrier amplifier 141A is connected thereto. A connection node N2A between the phase shifting line 131A and the phase shifting line 133A corresponds to the other input terminal of the hybrid coupler 130A, and the output end of the peak amplifier 142A is connected thereto.

A connection node N3A between the phase shifting line 132A and the phase shifting line 134A corresponds to one output terminal of the hybrid coupler 130A, and the switch S1A is connected thereto. A connection node N4A between the phase shifting line 133A and the phase shifting line 134A corresponds to the other output terminal of the hybrid coupler 130A, which is connected to the output circuit 170A and to the connection line 145.

Likewise, a connection node N1B between the phase shifting line 131B and the phase shifting line 132B corresponds to one input terminal of the hybrid coupler 130B, and the output end of the carrier amplifier 141B is connected thereto. A connection node N2B between the phase shifting line 131B and the phase shifting line 133B corresponds to the other input terminal of the hybrid coupler 130B, and the output end of the peak amplifier 142B is connected thereto.

A connection node N3B between the phase shifting line 132B and the phase shifting line 134B corresponds to one output terminal of the hybrid coupler 130B, and the switch S1B is connected thereto. A connection node N4B between the phase shifting line 133B and the phase shifting line 134B corresponds to the other output terminal of the hybrid coupler 130B, which is connected to the output circuit 170B and to the connection line 145.

In the examples of FIGS. 3 and 4, both the switch S1A in the amplification circuit 105A and the switch S1B in the amplification circuit 105B are set to the conductive state. In this way, impedances of the connection nodes N3A and N3B are short-circuited. Accordingly, all of the impedance when the phase shifting line 132A is viewed from the connection node N1A, the impedance when the phase shifting line 134A is viewed from the connection node N4A, the impedance when the phase shifting line 132B is viewed from the connection node N1B, and the impedance when the phase shifting line 134B is viewed from the connection node N4B are set to open.

An output signal from the carrier amplifier 141A is therefore synthesized with an output signal from the peak amplifier 142A at the connection node N2A through the phase shifting line 131A. Meanwhile, an output signal from the carrier amplifier 141B is synthesized with an output signal from the peak amplifier 142B at the connection node N2B through the phase shifting line 131B. That is to say, the amplification circuit 105A and the amplification circuit 105B each constitute a Doherty amplifier.

When the signal in the first frequency band is transmitted, as shown in FIG. 3, the impedance when the output terminal T2 is viewed from the connection node N4B is set to open by rendering the switch S2B in the output circuit 170B conductive. In this way, the signal amplified by the amplification circuit 105A is synthesized with the signal amplified by the amplification circuit 105B at the connection node N4A, and the synthesized signal is outputted from the output terminal T1.

In this case, a phase of a radio frequency signal θ₂ supplied from the branch circuit 115 to the amplification circuit 105B is adjusted to be advanced by 90° relative to a phase of a radio frequency signal θ₁ supplied from the branch circuit 115 to the amplification circuit 105A. The connection line 145 delays a phase of an output signal from the amplification circuit 105B by 90°. Accordingly, an output signal from the amplification circuit 105A and the output signal from the amplification circuit 105B are set to the same phase at the connection node N4A.

When the signal in the second frequency band is transmitted, as shown in FIG. 4, the impedance when the output terminal T1 is viewed from the connection node N4A is set to open by rendering the switch S2A in the output circuit 170A conductive. In this way, the signal amplified by the amplification circuit 105A is synthesized with the signal amplified by the amplification circuit 105B at the connection node N4B, and the synthesized signal is outputted from the output terminal T2.

In this case, the phase of the radio frequency signal θ₁ supplied from the branch circuit 115 to the amplification circuit 105A is adjusted to be advanced by 90° relative to the phase of the radio frequency signal θ₂ supplied from the branch circuit 115 to the amplification circuit 105B. The connection line 145 delays the phase of an output signal from the amplification circuit 105A by 90°. Accordingly, the output signal from the amplification circuit 105A and the output signal from the amplification circuit 105B are set to the same phase at the connection node N4B.

Since the amplification circuit 105A and the amplification circuit 105B each constitute the Doherty amplifier as described above, load impedances of the carrier amplifiers 141A and 141B can be increased by stopping the peak amplifiers 142A and 142B in a case where output power falls below a predetermined value. Accordingly, efficiency in low output power is increased so that an amount of back-off of about 6 dB can be realized.

Since the output ends of the two amplification circuits 105A and 105B are connected to each other through the connection line 145 having the electrical length equivalent to the quarter wavelength in the power amplification circuit 100 of the embodiment, directions of variations in load impedance when the antenna ANT is viewed from the output ends of the respective amplification circuits are opposite directions to each other in a case where the load variation occurs at the antenna ANT as will be described with reference to FIG. 5 and the like. In addition, the direction of the variation in load impedance when viewed from the carrier amplifier and the direction of the variation in load impedance when viewed from the peak amplifier are opposite directions to each other in each amplification circuit. Accordingly, the variations in output power associated with the load variation are offset between the amplification circuits and/or between the carrier amplifier and the peak amplifier, whereby the variation in output power is suppressed when the power amplification circuit 100 is viewed as a whole. It is therefore possible to enhance robustness against the load variation.

Variations of signal syntheses based on settings of the switches S1A and S1B in the respective amplification circuits, and variations in output power from the transmission circuit relative to the load variation will be described below by using FIGS. 5 to 20.

### Example 1: Parallel-Series Connection

FIGS. 5 to 8 are diagrams showing states of circuits and variations in output power in the case of Example 1 of the signal synthesis. In Example 1, the switch S1A of the amplification circuit 105A is set to the non-conductive state. Accordingly, the signal from the carrier amplifier 141A and the signal from the peak amplifier 142A are synthesized at the connection node N4A in the amplification circuit 105A. This synthesis will be referred to as a “parallel synthesis” in the present specification.

On the other hand, in the amplification circuit 105B, the switch S1B of the amplification circuit 105B is set to the conductive state. Accordingly, the amplification circuit 105B constitutes the Doherty amplifier as described with reference to FIG. 3. For this reason, the signal from the carrier amplifier 141B is unable to pass through the phase shifting lines 132B and 134B and is synthesized with the signal from the peak amplifier 142B at the connection node N2B. This synthesis will be referred to as a “series synthesis” in the present specification.

FIG. 5 is a diagram for explaining output states of the respective amplifiers in a case where a load impedance R_{ANT} of the antenna ANT becomes larger than a characteristic impedance R_{L} (R_{L}<R_{ANT}) at the time of high output when both the carrier amplifier and the peak amplifier in each of the amplification circuits are driven. In FIG. 5, the load impedances at respective points in a partial circuit diagram of the power amplification circuit 100 are indicated on the left side. Meanwhile, the variations in output power from the carrier amplifier 141A and the peak amplifier 142A on the route RT1 are depicted on an upper part on the right side of FIG. 5, and the variations in output power from the carrier amplifier 141B and the peak amplifier 142B on the route RT2 are depicted on a lower part thereon.

Note that a case where the radio frequency signal is transmitted from the output terminal T1 will be explained as an example in FIG. 5 and FIGS. 6 to 20 subsequent thereto. Accordingly, the output circuit 170B is omitted in the partial circuit diagrams of the power amplification circuit 100. Moreover, the load impedance R_{ANT} of the antenna ANT is represented as an impedance in a state where the phase shifting line 160A is included.

In FIG. 5, the load impedance at the connection node N4A becomes Lo by the phase shifting line 140A in the case where the load impedance R_{ANT} of the antenna ANT becomes Hi which is larger than the characteristic impedance R_{L}. The load impedance at the carrier amplifier 141A becomes Lo due to the respective phase shifting lines of the hybrid coupler 130A, and the load impedance at the peak amplifier 142A becomes Hi. Accordingly, on the route RT1, the output power from the carrier amplifier 141A is increased (a solid line LN10) due to a decrease in load as in a case where the phase in a graph in the drawing on the right is in a range from 0° to 90° or from 270° to 360°, and the output power from the peak amplifier 142A is decreased (a dashed line LN11) due to an increase in load on the other hand. Therefore, the variations in power attributed to the increase in output power from the carrier amplifier 141A and the decrease in output power from the peak amplifier 142A are offset. Thus, the output power synthesized in the amplification circuit 105A has flat characteristics as shown in a solid line LN12.

On the other hand, in the amplification circuit 105B on the route RT2, the load impedance becomes Hi at the connection node N4B by the connection line 145, the load impedance at the carrier amplifier 141B becomes Hi due to the respective phase shifting lines of the hybrid coupler 130B, and the load impedance at the peak amplifier 142A becomes Lo. Accordingly, on the route RT2, the output power from the carrier amplifier 141B is decreased (a solid line LN15) due to an increase in load, and the output power from the peak amplifier 142B is increased (a dashed line LN16) due to a decrease in load on the other hand. Therefore, the variations in power attributed to the decrease in output power from the carrier amplifier 141B and the increase in output power from the peak amplifier 142B are offset. Thus, the output power synthesized in the amplification circuit 105B also has flat characteristics as shown in a solid line LN17.

As a consequence, since the variations in output power associated with the variations in load impedance are offset in the respective amplification circuits of the amplification circuits 105A and 105B, the variation in output power from the power amplification circuit 100 as a whole is also suppressed.

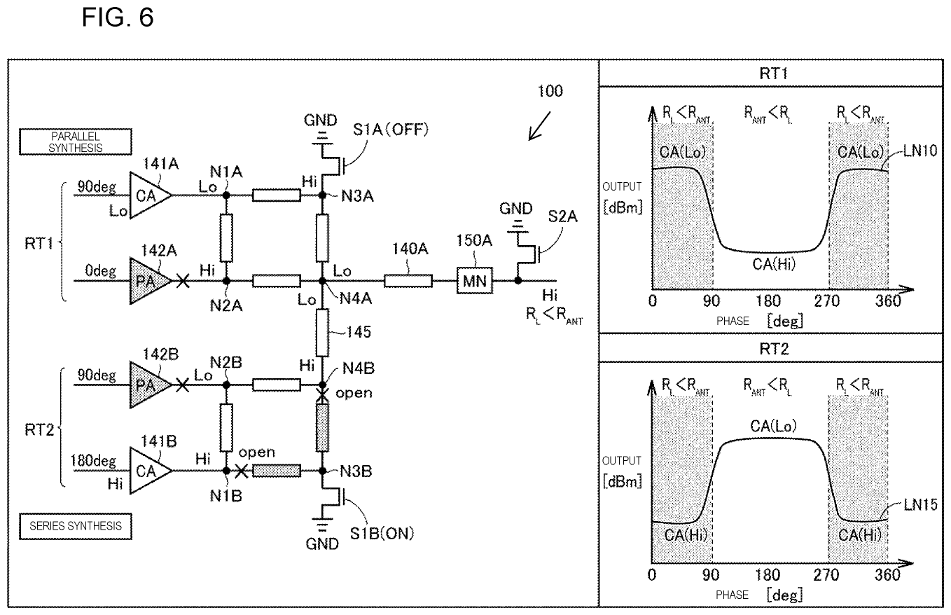

FIG. 6 shows, in the case where the load impedance R_{ANT} of the antenna ANT becomes larger than the characteristic impedance R_{L}, the output states of the respective amplifiers at the time of back-off when the peak amplifiers are stopped at the low output. As with FIG. 5, the load impedance at the carrier amplifier 141A is Lo and the load impedance at the carrier amplifier 141B is Hi in this case as well. Accordingly, the output power from the carrier amplifier 141A is increased and the output power from the carrier amplifier 141B is decreased.

On the other hand, the peak amplifiers 142A and 142B are stopped and no output power is generated from the peak amplifiers 142A and 142B. For this reason, the offset of the power variations does not take place in each of the amplification circuits alone as shown in FIG. 5. However, the variations in output power are offset in the synthesized signal from the amplification circuit 105A and the amplification circuit 105B due to the increase in output power from the carrier amplifier 141A and the decrease in output power from the carrier amplifier 141B. Accordingly, the variation in output power from the power amplification circuit 100 as a whole is suppressed as well.

Here, in the amplification circuit 105A of the parallel synthesis as well, the impedance at the carrier amplifier 141A is doubled when the peak amplifier 142A is stopped as compared to the case where the peak amplifier 142A is driven. Accordingly, the amplification circuit 105A can also realize the amount of back-off of 6 dB at the time of low output as with the amplification circuit 105B of the series synthesis constituting the Doherty amplifier.

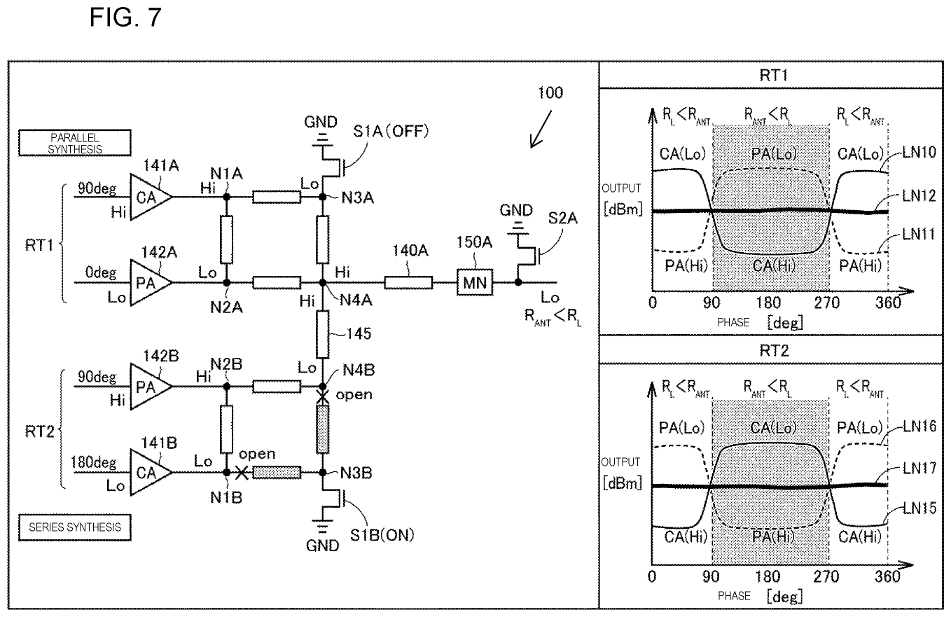

FIG. 7 shows, in the case where the load impedance R_{ANT} of the antenna ANT becomes smaller than the characteristic impedance R_{L} (R_{ANT}<R_{L}), the output states of the respective amplifiers at the time of high output when both the carrier amplifier and the peak amplifier are driven. In this case, the load impedance at the connection node N4A becomes Hi. As a consequence, the load impedance at the carrier amplifier 141A becomes Hi and the load impedance at the peak amplifier 142A becomes Lo. Accordingly, on the route RT1, the output power from the carrier amplifier 141A is decreased (the solid line LN10) due to an increase in load as in a case where the phase in a graph in the drawing on the right is in a range from 90° to 270°, and the output power from the peak amplifier 142A is increased (the dashed line LN11) due to a decrease in load on the other hand. Therefore, the variations in power attributed to the increase in output power from the carrier amplifier 141A and the decrease in output power from the peak amplifier 142A are offset. Thus, the output power synthesized in the amplification circuit 105A has flat characteristics as shown in the solid line LN12.

On the other hand, in the amplification circuit 105B on the route RT2, the load impedance becomes Lo at the connection node N4B by the connection line 145. Hence, the load impedance at the carrier amplifier 141B becomes Lo due to the respective phase shifting lines of the hybrid coupler 130B, and the load impedance at the peak amplifier 142A becomes Hi. Accordingly, on the route RT2, the output power from the carrier amplifier 141B is increased (the solid line LN15) due to a decrease in load, and the output power from the peak amplifier 142B is decreased (the dashed line LN16) due to an increase in load on the other hand. Therefore, the variations in power attributed to the increase in output power from the carrier amplifier 141B and the decrease in output power from the peak amplifier 142B are offset. Thus, the output power synthesized in the amplification circuit 105B also has flat characteristics as shown in the solid line LN17.

As described above, since the variations in output power associated with the variations in load impedance are offset in the respective amplification circuits of the amplification circuits 105A and 105B, the variation in output power from the power amplification circuit 100 as a whole is also suppressed as a consequence.

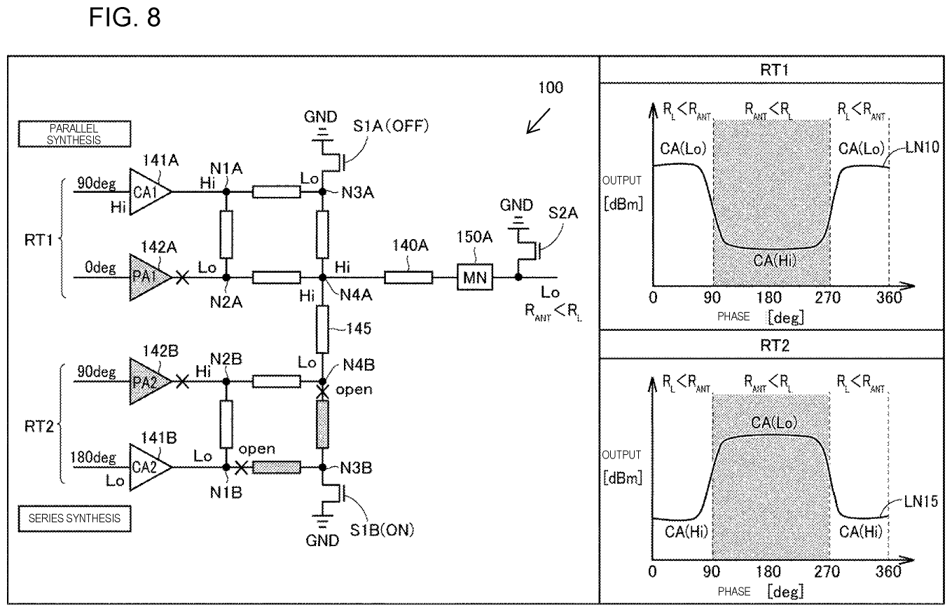

FIG. 8 shows, in the case where the load impedance R_{ANT} of the antenna ANT becomes smaller than the characteristic impedance R_{L}, the output states of the respective amplifiers at the time of back-off when the peak amplifiers are stopped. As with FIG. 7, the load impedance at the carrier amplifier 141A is Hi and the load impedance at the carrier amplifier 141B is Lo in this case as well. Accordingly, the output power from the carrier amplifier 141A is decreased and the output power from the carrier amplifier 141B is increased.

On the other hand, the peak amplifiers 142A and 142B are stopped and no output power is generated from the peak amplifiers 142A and 142B. For this reason, the offset of the power variations does not take place in each of the amplification circuits alone as shown in FIG. 7. However, the variations in output power are offset in the synthesized signal from the amplification circuit 105A and the amplification circuit 105B due to the decrease in output power from the carrier amplifier 141A and the increase in output power from the carrier amplifier 141B. Accordingly, the variation in output power from the power amplification circuit 100 as a whole is suppressed as well.

As described above, in the case where the route RT1 employs the parallel synthesis and the route RT2 employs the series synthesis, the variation in output power is suppressed in each of the case of high output and the case of low output despite the variation in load impedance. It is therefore possible to enhance robustness against the load variation.

### Example 2: Parallel-Parallel Connection

In Example 2, a case where both the amplification circuits 105A and 105B have configurations of the parallel synthesis is described. That is to say, in Example 2, each of the switches S1A and S1B in the amplification circuits 105A and 105B is set to the non-conductive state.

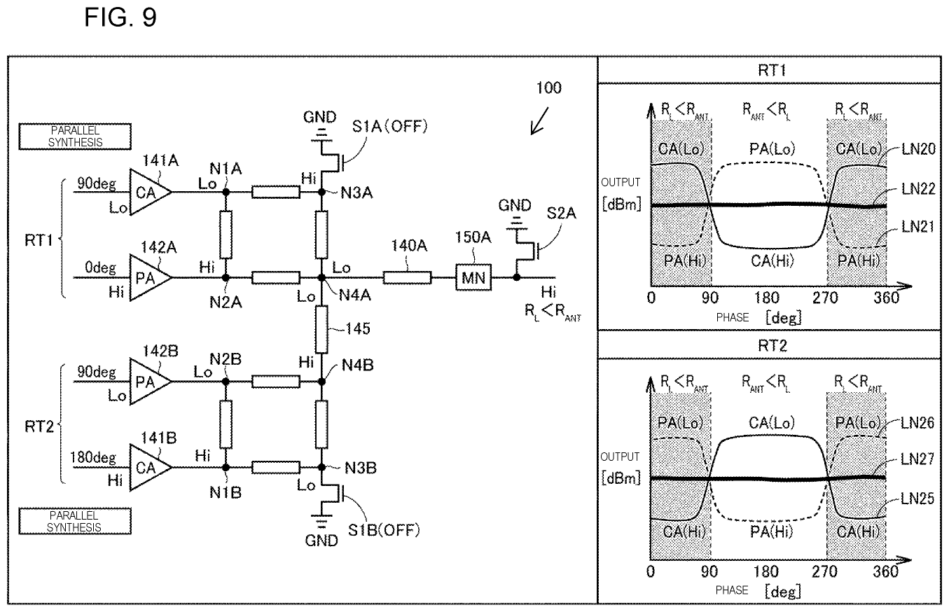

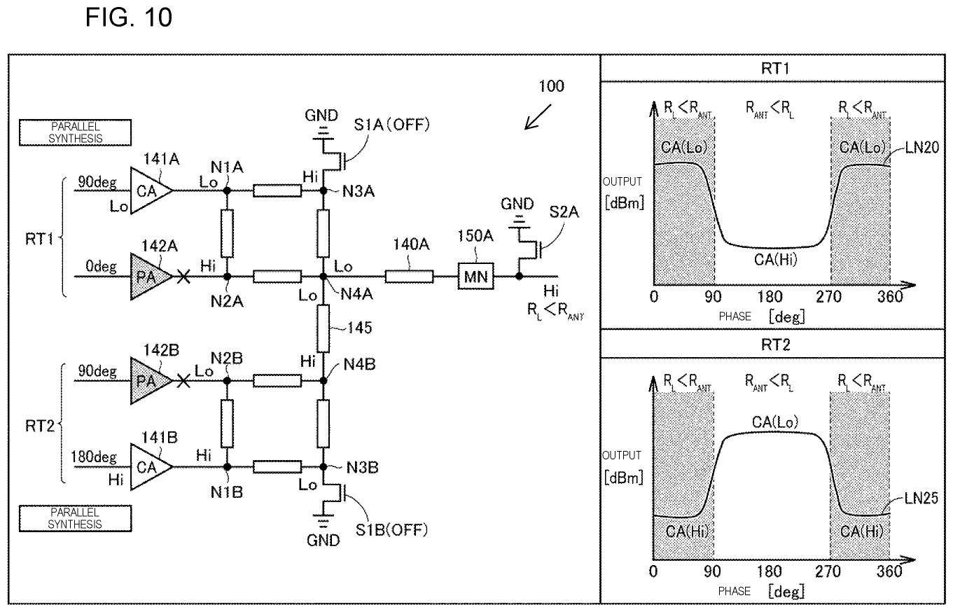

FIGS. 9 to 12 are diagrams showing states of circuits and variations in output power in the case of Example 2 of the signal synthesis. FIGS. 9 and 10 each show output states of the respective amplifiers in the case where the load impedance R_{ANT} of the antenna ANT is larger than the characteristic impedance R_{L} (R_{L}<R_{ANT}). FIG. 9 shows the states at the time of high output when the carrier amplifiers 141A and 141B as well as the peak amplifiers 142A and 142B are driven, and FIG. 10 shows the states at the time of low output when the peak amplifiers 142A and 142B are stopped.

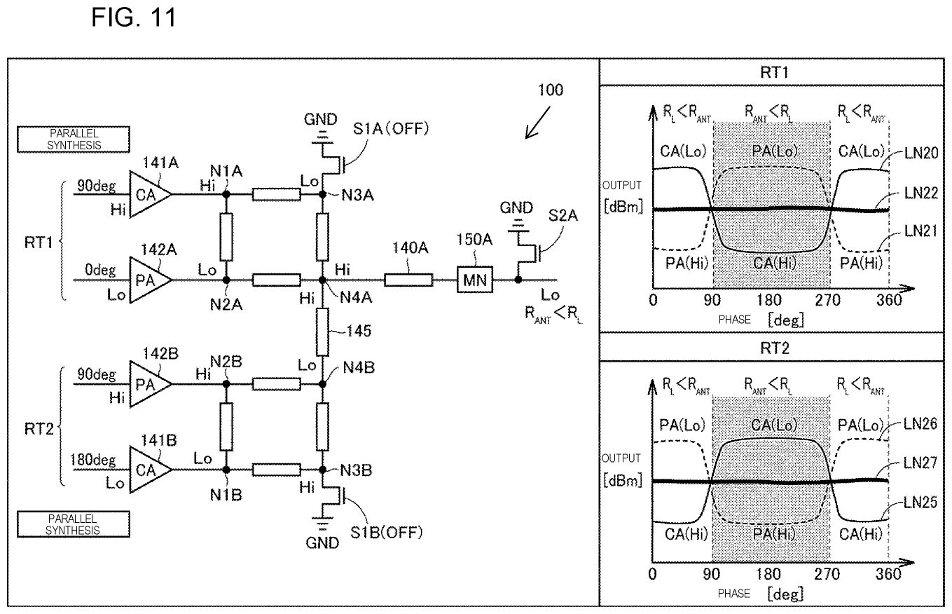

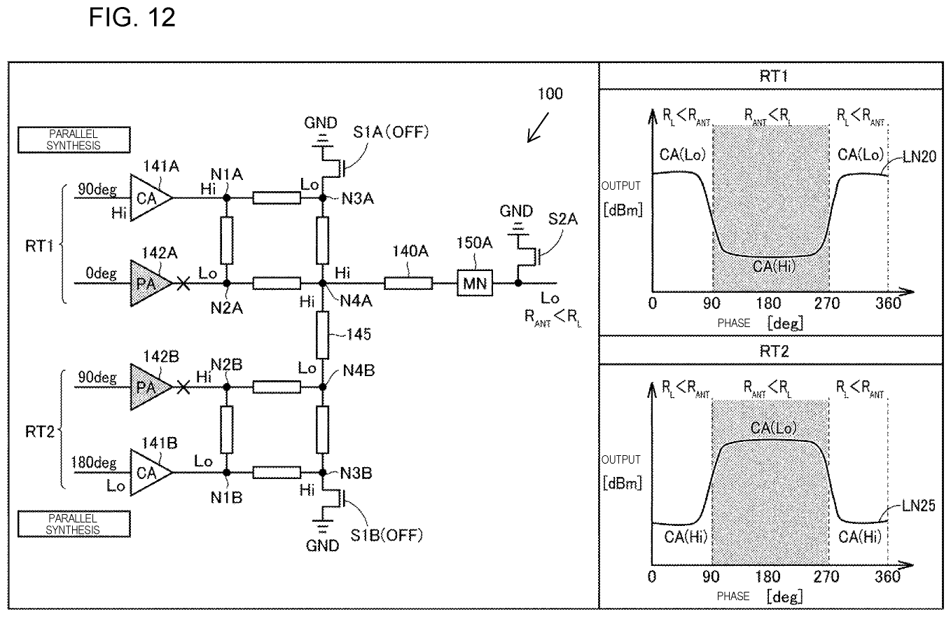

FIGS. 11 and 12 each show output states of the respective amplifiers in the case where the load impedance R_{ANT} of the antenna ANT is smaller than the characteristic impedance R_{L} (R_{ANT}<R_{L}). FIG. 11 shows the states at the time of high output, and FIG. 12 shows the states at the time of low output.

In the configuration where both the amplification circuits 105A and 105B employ the parallel synthesis as in Example 2, magnitude relationships between the load impedance in the carrier amplifier and the load impedance in the peak amplifier in the respective amplification circuits are inverted from each other at the time of high output, and the directions of variation in output power are also inverted from each other in association therewith (lines LN 20, LN21, LN25, and LN26 in FIGS. 9 and 11). Accordingly, the variation in output power from the carrier amplifier and the variation in output power from the peak amplifier are offset, whereby the output power from each of the amplifiers shows flat characteristics as indicated with lines LN22 and LN27 in FIGS. 9 and 11. Therefore, the variation in output power is suppressed in the synthesized signal of the output signal from the amplification circuit 105A and the output signal from the amplification circuit 105B.

Meanwhile, at the time of back-off when the peak amplifiers 142A and 142B are stopped, the magnitude relationships between the variation in load impedance of the amplification circuit 105A and the variation in load impedance of the amplification circuit 105B are inverted from each other in the case of a variation in antenna load as shown in FIGS. 10 and 12, and the directions of variation in output power are also inverted from each other (the lines LN 20 and LN25 in FIGS. 10 and 12). Accordingly, the variation in output power from the amplification circuit 105A and the variation in output power from the amplification circuit 105B are offset in the synthesized signal, whereby the variation in output power is also suppressed in the power amplification circuit 100 as a whole.

As described above, the variation in output power when the load impedance varies is also suppressed in the case where both the routes RT1 and RT2 employ the parallel synthesis. Accordingly, it is possible to enhance robustness against the load variation. In addition, the impedances at the carrier amplifiers 141A and 141B are increased in the case of low output as compared to the case of high output by stopping the peak amplifiers 142A and 142B. Thus, efficiency at the time of low output can be improved.

### Example 3: Series-Series Connection

In Example 3, a case where both the amplification circuits 105A and 105B have configurations of the series synthesis is described. That is to say, in Example 3, each of the switches S1A and S1B in the amplification circuits 105A and 105B is set to the conductive state.

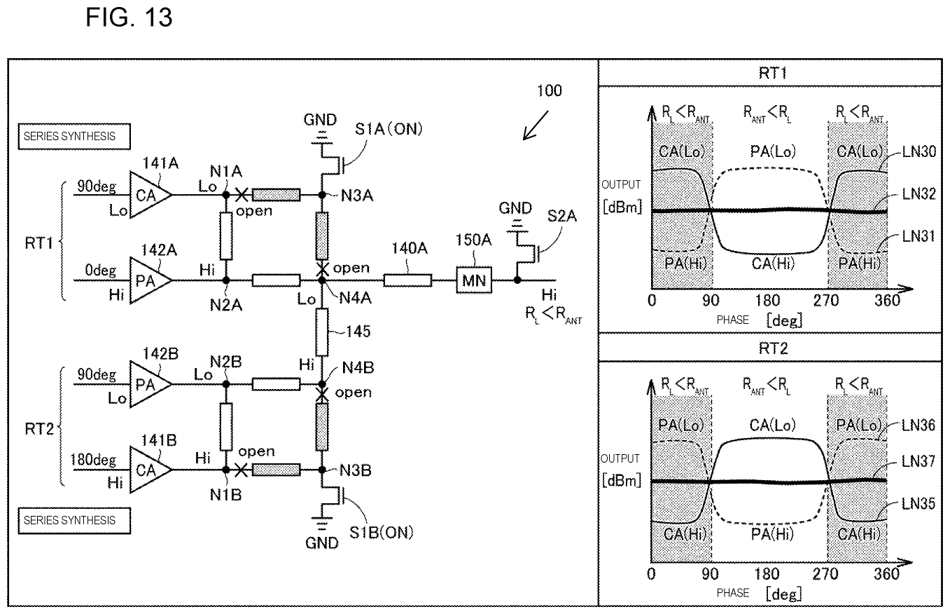

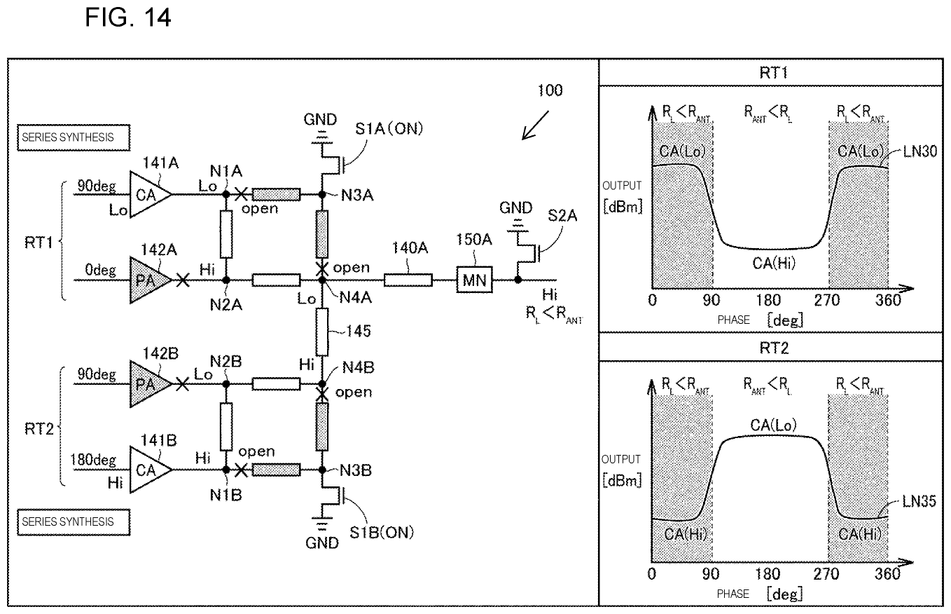

FIGS. 13 to 16 are diagrams showing states of circuits and variations in output power in the case of Example 3 of the signal synthesis. FIGS. 13 and 14 each show output states of the respective amplifiers in the case where the load impedance R_{ANT} of the antenna ANT is larger than the characteristic impedance R_{L} (R_{L}<R_{ANT}). FIG. 13 shows the states at the time of high output when the carrier amplifiers 141A and 141B as well as the peak amplifiers 142A and 142B are driven, and FIG. 14 shows the states at the time of low output when the peak amplifiers 142A and 142B are stopped.

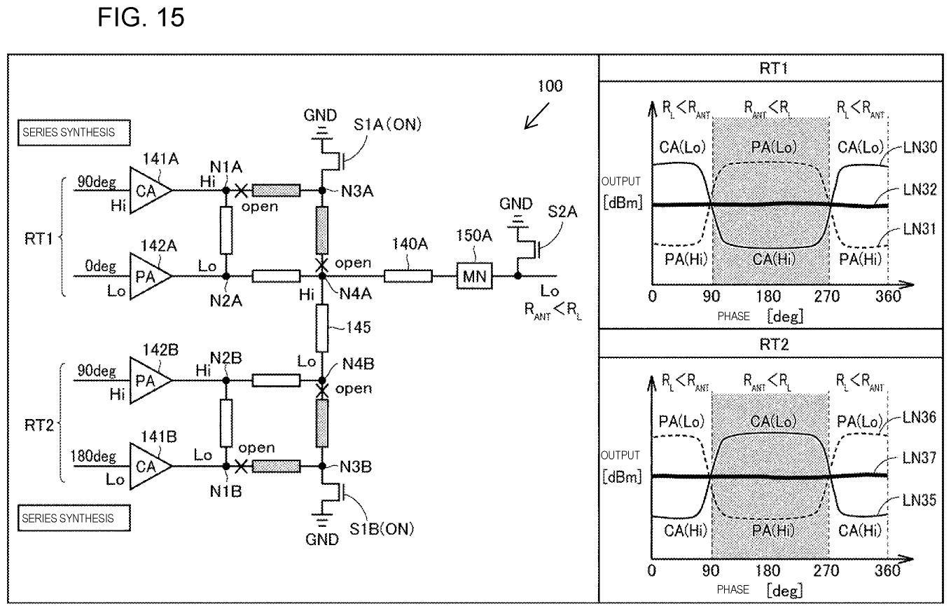

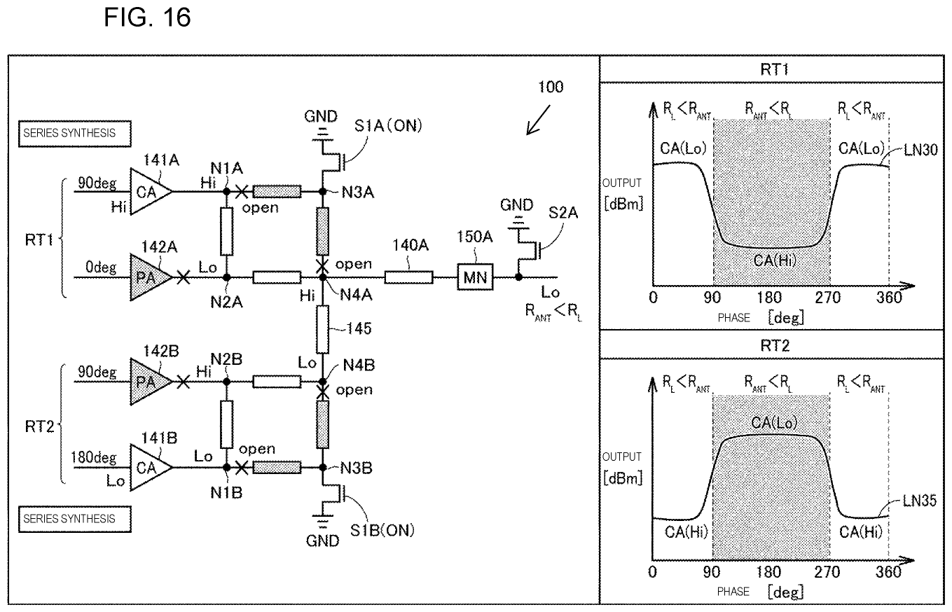

FIGS. 15 and 16 each show output states of the respective amplifiers in the case where the load impedance R_{ANT} of the antenna ANT is smaller than the characteristic impedance R_{L} (R_{ANT}<R_{L}). FIG. 15 shows the states at the time of high output, and FIG. 16 shows the states at the time of low output.

In the configuration where both the amplification circuits 105A and 105B employ the series synthesis, that is to say, constitute the Doherty amplifiers as in Example 3, the magnitude relationships between the load impedance in the carrier amplifier and the load impedance in the peak amplifier in the respective amplification circuits are inverted from each other at the time of high output, and the directions of variation in output power are also inverted from each other in association therewith (lines LN 30, LN31, LN35, and LN36 in FIGS. 13 and 15). Accordingly, the variation in output power from the carrier amplifier and the variation in output power from the peak amplifier are offset, whereby the output power from each of the amplifiers shows flat characteristics as indicated with lines LN32 and LN37 in FIGS. 13 and 15. Therefore, the variation in output power is suppressed in the synthesized signal of the output signal from the amplification circuit 105A and the output signal from the amplification circuit 105B.

Meanwhile, at the time of back-off when the peak amplifiers 142A and 142B are stopped, the magnitude relationships between the variation in load impedance of the amplification circuit 105A and the variation in load impedance of the amplification circuit 105B are inverted from each other in the case of a variation in antenna load as shown in FIGS. 14 and 16, and the directions of variation in output power are also inverted from each other (the lines LN 30 and LN35 in FIGS. 14 and 16). Accordingly, the variation in output power from the amplification circuit 105A and the variation in output power from the amplification circuit 105B are offset in the synthesized signal, whereby the variation in output power is also suppressed in the power amplification circuit 100 as a whole.

As described above, the variation in output power when the load impedance varies is also suppressed in the case where both the routes RT1 and RT2 employ the series synthesis. Accordingly, it is possible to enhance robustness against the load variation. In addition, the impedances at the carrier amplifiers 141A and 141B are increased in the case of low output as compared to the case of high output by stopping the peak amplifiers 142A and 142B. Thus, efficiency at the time of low output can be improved.

### Example 4: Series-Parallel Connection

In Example 4, a case where the amplification circuit 105A has a configuration of the series synthesis and the amplification circuit 105B has a configuration of the parallel synthesis is described. That is to say, in Example 4, the switch S1A in the amplification circuit 105A is set to the conductive state and the switch S1B in the amplification circuit 105B is set to the non-conductive state.

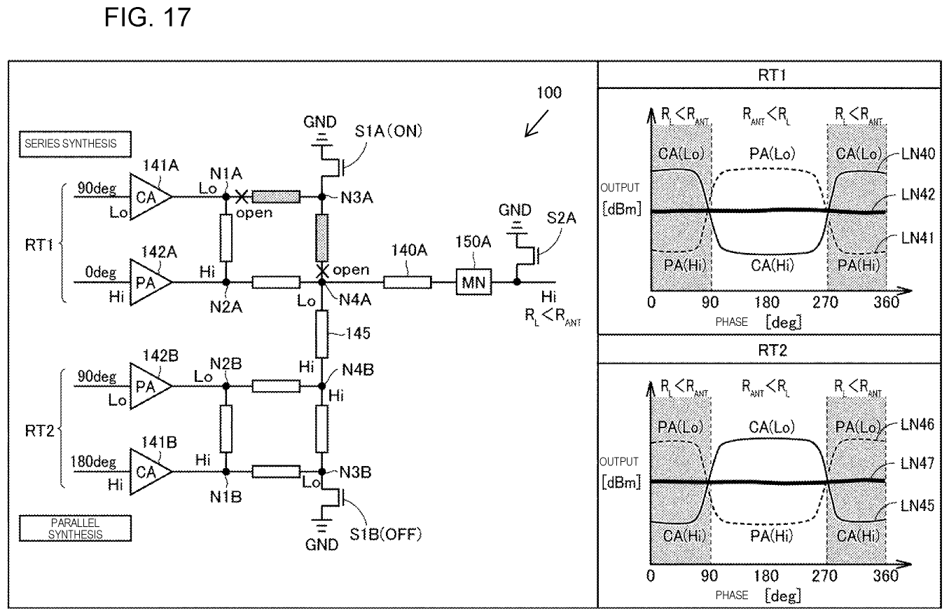

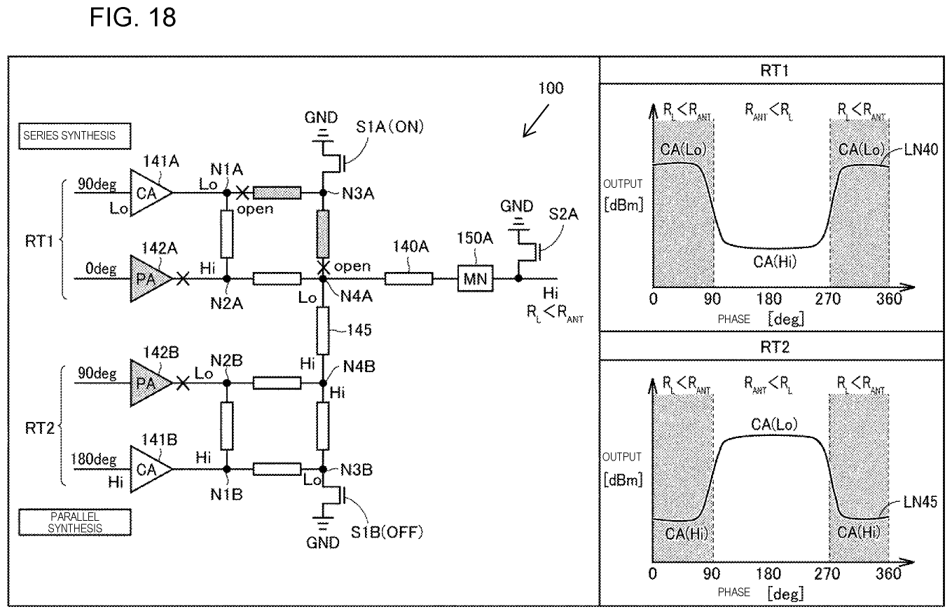

FIGS. 17 to 20 are diagrams showing states of circuits and variations in output power in the case of Example 4 of the signal synthesis. FIGS. 17 and 18 each show output states of the respective amplifiers in the case where the load impedance R_{ANT} of the antenna ANT is larger than the characteristic impedance R_{L} (R_{L}<R_{ANT}). FIG. 17 shows the states at the time of high output when the carrier amplifiers 141A and 141B as well as the peak amplifiers 142A and 142B are driven, and FIG. 18 shows the states at the time of low output when the peak amplifiers 142A and 142B are stopped.

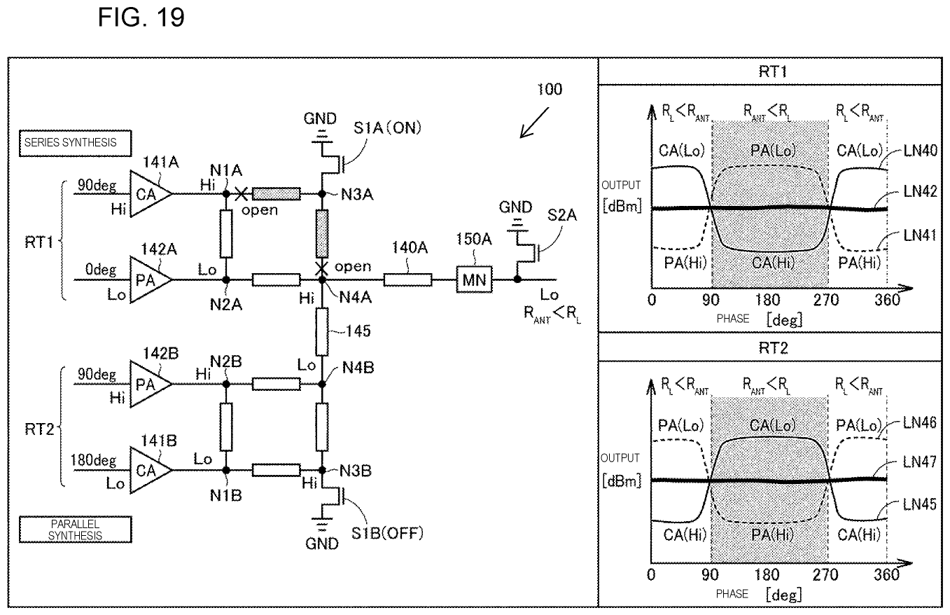

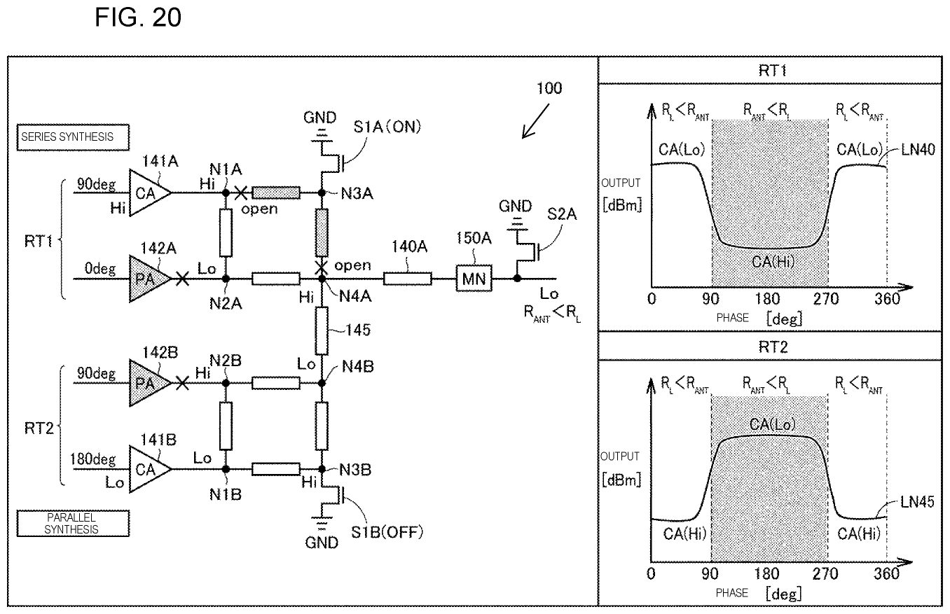

FIGS. 19 and 20 each show output states of the respective amplifiers in the case where the load impedance R_{ANT} of the antenna ANT is smaller than the characteristic impedance R_{L} (R_{ANT}<R_{L}). FIG. 19 shows the states at the time of high output, and FIG. 20 shows the states at the time of low output.

In the case where the amplification circuit 105A employs the series synthesis and the amplification circuit 105B employs the parallel synthesis as in Example 4, the magnitude relationships between the load impedance in the carrier amplifier and the load impedance in the peak amplifier in the respective amplification circuits are inverted from each other at the time of high output, and the directions of variation in output power are also inverted from each other in association therewith (lines LN 40, LN41, LN45, and LN46 in FIGS. 17 and 19). Accordingly, the variation in output power from the carrier amplifier and the variation in output power from the peak amplifier are offset, whereby the output power from each of the amplifiers shows flat characteristics as indicated with lines LN42 and LN47 in FIGS. 17 and 19. Therefore, the variation in output power is suppressed in the synthesized signal of the output signal from the amplification circuit 105A and the output signal from the amplification circuit 105B.

Meanwhile, at the time of back-off when the peak amplifiers 142A and 142B are stopped, the magnitude relationships between the variation in load impedance of the amplification circuit 105A and the variation in load impedance of the amplification circuit 105B are inverted from each other in the case of a variation in antenna load as shown in FIGS. 18 and 20, and the directions of variation in output power are also inverted from each other (the lines LN 40 and LN45 in FIGS. 18 and 20). Accordingly, the variation in output power from the amplification circuit 105A and the variation in output power from the amplification circuit 105B are offset in the synthesized signal, whereby the variation in output power is also suppressed in the power amplification circuit 100 as a whole.

As described above, the variation in output power when the load impedance varies is also suppressed in the case where the route RT1 employs the series synthesis and the route RT2 employs the parallel synthesis. Accordingly, it is possible to enhance robustness against the load variation. In addition, the impedances at the carrier amplifiers 141A and 141B are increased in the case of low output as compared to the case of high output by stopping the peak amplifiers 142A and 142B. Thus, efficiency at the time of low output can be improved.

Here, the output circuit 170B that transfers the signal to the output terminal T2 is omitted in FIGS. 5 to 20. However, since the power amplification circuit 100 has the symmetric configuration with respect to the connection line 145, the same states as those described in Examples 1 to 4 are eventually available in the case of outputting the radio frequency signal from the output terminal T2 as well. Accordingly, a dual-band type configuration to radiate radio waves in two different frequency bands by switching the output terminals as described with reference to FIGS. 3 and 4 can also enhance robustness against the load variation and realize the amount of back-off of 6 dB by improving efficiency at the time of low output concerning the signals in the two frequency bands.

The “input terminal T0”, the “output terminal T1”, and the “output terminal T2” in the embodiment correspond to an “input terminal”, a “first output terminal”, and a “second output terminal” in the present disclosure, respectively. The “amplification circuit 105A” and the “amplification circuit 105B” in the embodiment correspond to a “first amplification circuit” and a “second amplification circuit” in the present disclosure, respectively. The “output circuit 170A” and the “output circuit 170B” in the embodiment correspond to a “first output circuit” and a “second output circuit” in the present disclosure, respectively. The “switch S1A”, the “switch S1B”, the “switch S2A”, and the “switch S2B” in the embodiment correspond to a “first switch” to a “fourth switch” in the present disclosure, respectively.

The “hybrid coupler 130A” and the “hybrid coupler 130B” in the embodiment correspond to a “first hybrid coupler” and a “second hybrid coupler” in the present disclosure, respectively. The “carrier amplifier 141A” and the “carrier amplifier 141B” in the embodiment correspond to a “first carrier amplifier” and a “second carrier amplifier” in the present disclosure, respectively. The “peak amplifier 142A” and the “peak amplifier 142B” in the embodiment correspond to a “first peak amplifier” and a “second peak amplifier” in the present disclosure, respectively.

Each of the “phase shifting line 131A” and the “phase shifting line 131B” in the embodiment corresponds to a “first phase shifting line” in the present disclosure. Each of the “phase shifting line 132A” and the “phase shifting line 132B” in the embodiment corresponds to a “second phase shifting line” in the present disclosure. Each of the “phase shifting line 133A” and the “phase shifting line 133B” in the embodiment corresponds to a “third phase shifting line” in the present disclosure. Each of the “phase shifting line 134A” and the “phase shifting line 134B” in the embodiment corresponds to a “fourth phase shifting line” in the present disclosure. The “phase shifting line 140A”, the “phase shifting line 160A”, the “phase shifting line 140B”, and the “phase shifting line 160B” in the embodiment correspond to a “fifth phase shifting line” to an “eighth phase shifting line” in the present disclosure, respectively.

The “matching circuit 150A” and the “matching circuit 150B” in the embodiment correspond to a “first matching circuit” and a “second matching circuit” in the present disclosure, respectively. The “connection node N1A” to the “connection node N4A” in the embodiment correspond to a “first connection node” to a “fourth connection node” in the present disclosure, respectively. The “connection node N1B” to the “connection node N4B” in the embodiment correspond to a “fifth connection node” to an “eighth connection node” in the present disclosure, respectively.

The embodiment disclosed herein is illustrative in all aspects and should not be considered as restrictive. The scope of the present invention is defined not by the explanations of the above-described embodiment but by the scope of the claims, and includes all modifications within the scope and meanings equivalent to the scope of the claims.
1 communication device, 10 transmission circuit, 20 BBIC, 30 RFIC, 40 power supply circuit, 50 bias control circuit, 100 power amplification circuit, 105A, 105B amplification circuit, 110 phase shifting circuit, 115 branch circuit, 120A, 120B, 130A, 130B hybrid coupler, 131A to 134A, 131B to 134B, 140A, 140B, 160A, 160B phase shifting line, 141A, 141B carrier amplifier, 142A, 142B peak amplifier, 145 connection line, 150A, 150B matching circuit, 170A, 170B output circuit, 410 MPC, 420 power supply selection circuit, 430 digital ET, ANT antenna, GND ground potential, N1A to N4A, N1B to N4B connection node, RT1, RT2 route, S1A, S1B, S2A, S2B switch, SP1, SP2 power feeding point, T0, T3, T4, T10 input terminal, T1, T2, T11, T12 output terminal, VB battery voltage, Vcc power supply voltage

1. A transmission circuit for amplifying a radio frequency signal and transmitting the amplified signal to a radiating element, the transmission circuit comprising:
an input terminal that receives the radio frequency signal;
a first output terminal and a second output terminal that connect to the radiating element;
a first amplification circuit and a second amplification circuit that are configured to amplify the radio frequency signal received by the input terminal;
a connection line that connects the first amplification circuit to the second amplification circuit;
a first output circuit connected to the first amplification circuit and configured to transfer the amplified signal to the first output terminal;
a second output circuit connected to the second amplification circuit and configured to transfer the amplified signal to the second output terminal; and
a first switch and a second switch,
wherein the first amplification circuit comprises a first carrier amplifier, a first peak amplifier, and a first hybrid coupler,
wherein the second amplification circuit comprises a second carrier amplifier, a second peak amplifier, and a second hybrid coupler,
wherein each of the first hybrid coupler and the second hybrid coupler comprises a first phase shifting line, a second phase shifting line, a third phase shifting line, and a fourth phase shifting line which are annularly connected,
wherein a first connection node between the first phase shifting line and the second phase shifting line of the first hybrid coupler is connected to an output of the first carrier amplifier,
wherein a second connection node between the first phase shifting line and the third phase shifting line of the first hybrid coupler is connected to an output of the first peak amplifier,
wherein a third connection node between the second phase shifting line and the fourth phase shifting line of the first hybrid coupler is connected to a ground potential through the first switch,
wherein a fourth connection node between the third phase shifting line and the fourth phase shifting line of the first hybrid coupler is connected to the first output terminal through the first output circuit,
wherein a fifth connection node between the first phase shifting line and the second phase shifting line of the second hybrid coupler is connected to an output of the second carrier amplifier,
wherein a sixth connection node between the first phase shifting line and the third phase shifting line of the second hybrid coupler is connected to an output of the second peak amplifier,
wherein a seventh connection node between the second phase shifting line and the fourth phase shifting line of the second hybrid coupler is connected to the ground potential through the second switch,
wherein an eighth connection node between the third phase shifting line and the fourth phase shifting line of the second hybrid coupler is connected to the second output terminal through the second output circuit,
wherein the connection line is connected between the fourth connection node and the eighth connection node,
wherein radio frequency signals having different phases from each other are supplied to the first amplification circuit and the second amplification circuit, and
wherein the connection line has an electrical length equal to the phase shifting lines in the first hybrid coupler or the second hybrid coupler.

2. The transmission circuit according to claim 1, further comprising:
a branch circuit configured to divide the radio frequency signal received by the input terminal into signals for the first amplification circuit and the second amplification circuit.

3. The transmission circuit according to claim 1, further comprising:
a third switch connected between the first output circuit and the ground potential; and
a fourth switch connected between the second output circuit and the ground potential,
wherein the third switch is in a non-conductive state and the fourth switch is in a conductive state when the radio frequency signal is supplied from the first output terminal to the radiating element, and
the fourth switch is in the non-conductive state and the third switch is in the conductive state when the radio frequency signal is supplied from the second output terminal to the radiating element.

4. The transmission circuit according to claim 3,
wherein the radiating element is configured to radiate radio waves in two different frequency bands, and
wherein the third switch and the fourth switch are switched in accordance with the frequency band of the radio frequency signal supplied to the radiating element.

5. The transmission circuit according to claim 3,
wherein the first output circuit comprises:
a fifth phase shifting line having a first end connected to the fourth connection node, and
a sixth phase shifting line having a first end connected to the first output terminal,
wherein the third switch is connected to a path that connects a second end of the fifth phase shifting line to a second end of the sixth phase shifting line,
wherein the second output circuit comprises:
a seventh phase shifting line having a first end connected to the eighth connection node, and
an eighth phase shifting line having a first end connected to the second output terminal, and
wherein the fourth switch is connected to a path that connects a second end of the seventh phase shifting line to a second end of the eighth phase shifting line.

6. The transmission circuit according to claim 5,
wherein the first output circuit further comprises a first matching circuit adapted to the radio frequency signal transmitted from the first output terminal, and
wherein the second output circuit further comprises a second matching circuit adapted to the radio frequency signal transmitted from the second output terminal.

7. The transmission circuit according to claim 1,
wherein the first carrier amplifier, the first peak amplifier, the second carrier amplifier, and the second peak amplifier are in a driven state when electric power of the radio frequency signal supplied to the input terminal is larger than a predetermined electric power, and
wherein the first carrier amplifier and the second carrier amplifier are in the driven state and the first peak amplifier and the second peak amplifier are in an undriven state when the electric power of the radio frequency signal supplied to the input terminal is smaller than the predetermined electric power.

8. The transmission circuit according to claim 1,
wherein the first amplification circuit is configured to operate as a Doherty amplifier when the first switch is in a conductive state, and
wherein the second amplification circuit is configured to operate as a Doherty amplifier when the second switch is in the conductive state.

9. The transmission circuit according to claim 1, wherein when the radio frequency signal is transmitted from the first output terminal to the radiating element:
a first signal is supplied to the first carrier amplifier and the second peak amplifier, the first signal having a phase advanced by 90° relative to a radio frequency signal supplied to the first peak amplifier, and
a second signal is supplied to the second carrier amplifier, the second signal having a phase advanced by 180° relative to the radio frequency signal supplied to the first peak amplifier.

10. The transmission circuit according to claim 1, wherein when the radio frequency signal is transmitted from the second output terminal to the radiating element:
a first signal is supplied to the second carrier amplifier and the first peak amplifier, the first signal having a phase advanced by 90° relative to a radio frequency signal supplied to the second peak amplifier, and
a second signal is supplied to the first carrier amplifier, the second signal having a phase advanced by 180° relative to the radio frequency signal supplied to the second peak amplifier.

11. A communication device comprising:
the transmission circuit according to claim 1;
a signal processing circuit configured to process the radio frequency signal supplied to the transmission circuit; and
the radiating element configured to radiate, as a radio wave, the radio frequency signal amplified by the transmission circuit.
